(19) United States
(12) Patent Application Publication
(10) Pub. No.: US 2023/0107826 A1
(43) Pub. Date: Apr. 6, 2023

(54) Organic Light Emitting Device and Display Apparatus

(71) Applicant: BOE Technology Group Co., Ltd., Beijing (CN)

(72) Inventors: Yuqian SUN, Beijing (CN); Yang LIU, Beijing (CN)

(21) Appl. No.: 17/603,009

(22) PCT Filed: Dec. 28, 2020
(86) PCT No.: PCT/CN2020/139813

§ 371 Date: Oct. 12, 2021

(51) Int. Cl. H10K 50/11; H10K 50/15; H10K 85/60; H10K 50/18; H10K 50/16

(52) U.S. Cl. CPC H01L 51/5004; H01L 51/5056; H01L 51/006; H01L 51/0073; H01L 51/0067; H01L 51/0054; H01L 51/0072; H01L 51/0074; H01L 51/5096; H01L 51/5072

(57) ABSTRACT

An embodiment of the present disclosure provides an organic light emitting device, including an anode, a cathode, a light emitting layer arranged between the anode and the cathode, and an electron block layer arranged on a side of the light emitting layer facing the anode, the light emitting layer including a host material and a dopant material, the host material including an N-type material and a P-type material, and a material of the electron block layer and the N-type material satisfying: 2.75 eV≤|LUMO_{N-host}−HOMO_{EBL}|<3.05 eV; 0.3< HOMO_{N-host}−HOMO_{EBL}|≤1 eV, and |HOMO_{EBL}|<|HOMO_{N-host}|, a difference between a peak wavelength of a luminescence spectrum curve of an exciplex formed by the material of the electron block layer and the N-type material and an absorption band edge wavelength of an absorption spectrum curve of the dopant material being Δλ, Δλ>30 nm.

### CROSS-REFERENCE TO RELATED APPLICATION

The present application is a U.S. National Phase Entry of International Application No. PCT/CN2020/139813 having an international filing date of Dec. 28, 2020, the content of which is hereby incorporated by reference.

### TECHNICAL FIELD

Embodiments of the present disclosure relate to, but are not limited to, the field of display technology, in particular to an organic light emitting device and a display apparatus.

### BACKGROUND

At present, an organic light emitting device (OLED) is generally composed of an anode, a hole transport layer, an electron block layer, a light emitting layer, a hole block layer, an electron transport layer, and a cathode. The electron block layer and the hole block layer may block excess electrons, holes, and excitons that are not utilized by the light emitting layer. However, since the electron block layer is unstable to electrons, it will break down during long-term use, resulting in a failure of the device.

### SUMMARY

The following is a summary of subject matter described in detail herein. This summary is not intended to limit the protection scope of claims.

An embodiment of the present disclosure provides an organic light emitting device, including an anode, a cathode, a light emitting layer arranged between the anode and the cathode, and an electron block layer arranged on a side of the light emitting layer facing the anode, the light emitting layer including a host material and a dopant material, the host material including an N-type material and a P-type material, and a material of the electron block layer and the N-type material satisfying: 2.75 eV≤|LUMO_{N-host}−HOMO_{EBL}|<3.05 eV; 0.3<|HOMO_{N-host}−HOMO_{EBL}|≤1 eV, and |HOMO_{EBL}|<|HOMO_{N-host}|, wherein LUMO_{N-host} is the lowest unoccupied molecular orbit energy level of the N-type material, HOMO_{EBL} is the highest occupied molecular orbit energy level of the material of the electron block layer, and HOMO_{N-host} is the highest occupied molecular orbit energy level of the N-type material; a difference between a peak wavelength of a luminescence spectrum curve of an exciplex formed by the material of the electron block layer and the N-type material and an absorption band edge wavelength of an absorption spectrum curve of the dopant material is Δλ, Δλ>30 nm.

Optionally, the organic light emitting device further includes a hole transport layer arranged between the anode and the electron block layer, a material of the hole transport layer and the material of the electron block layer satisfying: 0 eV≤|HOMO_{HTL}−HOMO_{EBL}|≤0.2 eV, wherein HOMO_{HTL} is the highest occupied molecular orbit energy level of the material of the hole transport layer.

Optionally, the material of the electron block layer includes a compound having the following structural formula.

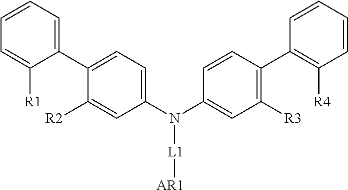

L1 is a single bond, a benzene ring, or a biphenyl;

R1, R2, R3, and R4 are independently selected from: hydrogen, CHO, C(═O)R5, P(═O)R5, S(═O)R5, cyano, nitro-silyl, boryl, hydroxyl, carboxyl, C1-C4 linear alkyl, C3-C40 cycloalkyl or branched alkyl, C2-C40 alkenyl or alkynyl, and aryl or heteroaryl having 5-60 ring atoms, wherein R5 in C(═O)R5, P(═O)R5, and S(═O)R5 is independently selected from: C1-C4 linear alkyl, C3-C40 cycloalkyl or branched alkyl, C2-C40 alkenyl or alkynyl, and aryl or heteroaryl having 5-60 ring atoms; AR1 is any one of the following: substituted or unsubstituted diphenylfluorene, substituted or unsubstituted spirobifluorene, and substituted or unsubstituted spirofluorene heteroanthracene.

Optionally, AR1 is selected from any one of the following structures.

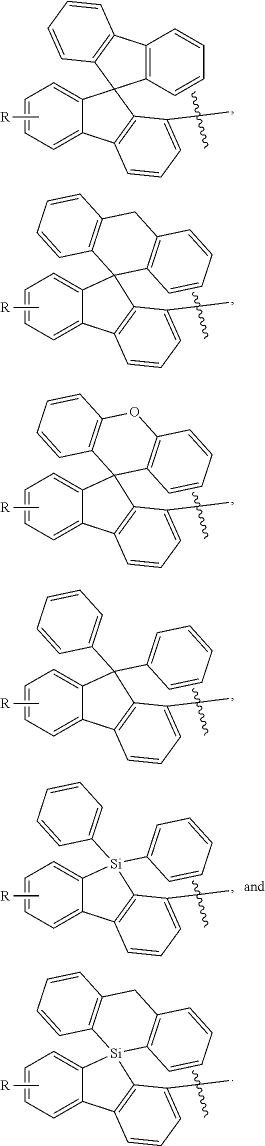

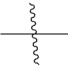

represents a position connected to L1, and R represents H or hydrocarbyl on a spiro ring.

Optionally, the material of the electron block layer includes any one or more of the following.

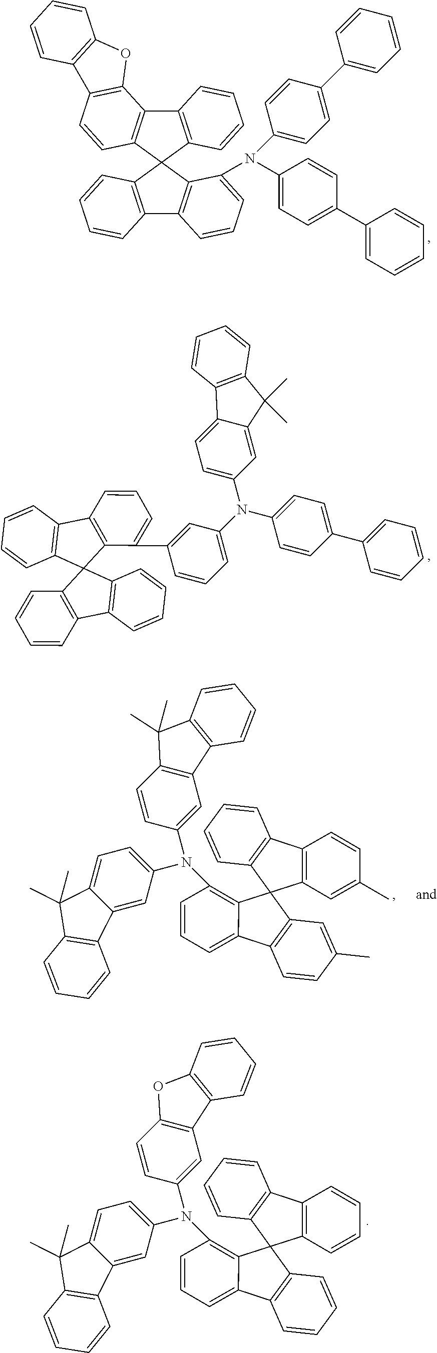

Optionally, the N-type material includes a compound having the following structural formula.

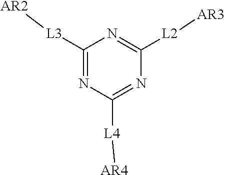

L2, L3, and L4 are independently a single bond, a benzene ring, or a biphenyl.

AR2 is selected from the following structures.

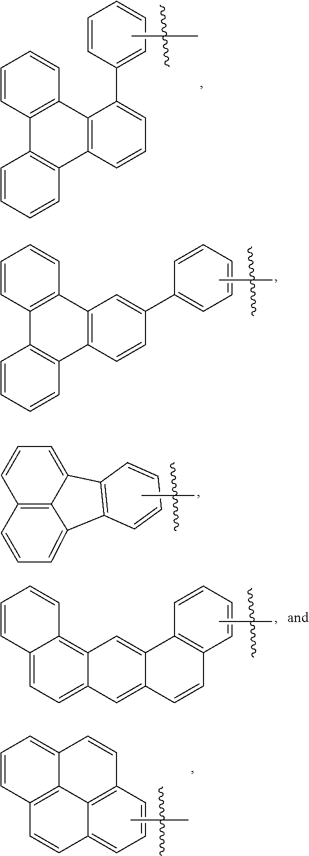

wherein

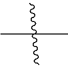

represents a position connected to L3.

AR3 and AR4 are independently selected from: substituted or unsubstituted C6-C30 aryl, and substituted or unsubstituted heteroaryl having 5-30 ring atoms.

Optionally, the N-type material includes a compound having the following structural formula.

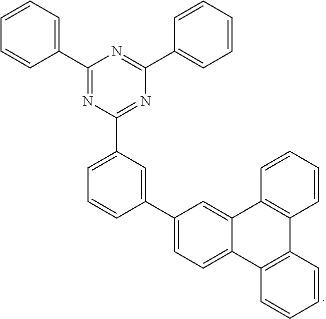 [SMILES: c1ccc(-c2nc(-c3ccccc3)nc(-c3cccc(-c4ccc5c6ccccc6c6ccccc6c5c4)c3)n2)cc1]

Optionally, the P-type material includes a compound having the following structural formula.

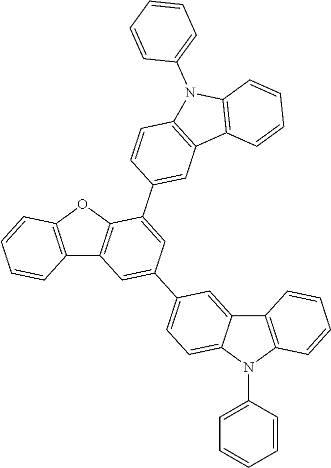 [SMILES: c1ccc(-n2c3ccccc3c3cc(-c4cc(-c5ccc6c(c5)c5ccccc5n6-c5ccccc5)c5oc6ccccc6c5c4)ccc32)cc1]

Optionally, the dopant material includes any one or more of the following: coumarin dyes, quinacridone derivatives, polycyclic aromatic hydrocarbons, diamine anthracene derivatives, carbazole derivatives, and metal complexes.

Optionally, the material of the hole transport layer includes a compound having the following structural formula.

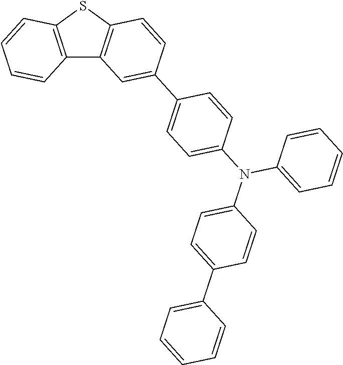 [SMILES: c1ccc(-c2ccc(N(c3ccccc3)c3ccc(-c4ccc5sc6ccccc6c5c4)cc3)cc2)cc1]

Optionally, the organic light emitting device further includes a hole injection layer arranged between the hole transport layer and the anode, a material of the hole injection layer including 4,4′,4″-tris[2-naphthylphenyl amino]triphenylamine.

Optionally, the organic light emitting device further includes a hole block layer arranged on a side of the light emitting layer facing the cathode, a material of the hole block layer including a compound having the following structural formula.

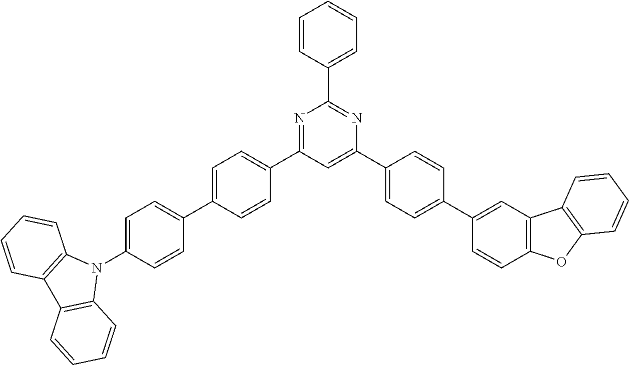 [SMILES: c1ccc(-c2nc(-c3ccc(-c4ccc(-n5c6ccccc6c6ccccc65)cc4)cc3)cc(-c3ccc(-c4ccc5oc6ccccc6c5c4)cc3)n2)cc1]

Optionally, the organic light emitting device further includes an electron transport layer arranged between the hole block layer and the cathode, a material of the electron transport layer including any one or more of the following: 8-hydroxyquinoline lithium or 8-hydroxyquinoline aluminum.

An embodiment of the present disclosure further provides a display apparatus including the organic light emitting device.

Other aspects will become apparent upon reading and understanding accompanying drawings and the detailed description.

### BRIEF DESCRIPTION OF DRAWINGS

Accompanying drawings are used to provide a further understanding of technical solutions of the present disclosure, form a part of the specification, and explain technical solutions of the present disclosure together with embodiments of the present disclosure, while they do not constitute a limitation on the technical solutions of the present disclosure. Shapes and sizes of various components in the drawings do not reflect true scales and are intended to illustrate schematically contents of the present disclosure only.

FIG. 1 is a schematic diagram of a planar structure of a display area of a display substrate.

FIG. 2 is a schematic diagram of a sectional structure of the display substrate of FIG. 1.

FIG. 3 is a schematic diagram of a structure of an organic light emitting device according to an exemplary embodiment of the present disclosure.

FIG. 4 is a schematic diagram of a material energy level relationship of some film layers in an organic light emitting device according to an exemplary embodiment of the present disclosure.

FIG. 5 is a spectrum diagram of materials of some film layers in an organic light emitting device according to an exemplary embodiment of the present disclosure.

The Reference Signs are as Follows.

101-base substrate, 102-driving circuit layer, 103-light emitting structure layer, 104-encapsulation structure layer; 201-first insulating layer, 202-second insulating layer, 203-third insulating layer, 204-fourth insulating layer, 205-planarization layer, 210-driving transistor, 211-storage capacitor; 300-pixel definition layer; 301-anode, 302-light emitting layer, 303-cathode, 304-hole injection layer, 305-hole transport layer, 306-electron block layer, 307-hole block layer, 308-electron transport layer, 309-electron injection layer; 310-light emitting device; 401-first encapsulation layer, 402-second encapsulation layer, and 403-third encapsulation layer.

### DETAILED DESCRIPTION

The embodiments herein may be implemented in a plurality of different ways. A person of ordinary skills in the art will readily understand a fact that implementations and contents may be transformed into a variety of forms without departing from the spirit and scope of the present disclosure. Therefore, the present disclosure should not be construed as being limited only to what is described in the following embodiments. The embodiments and features in the embodiments in the present disclosure may be combined randomly if there is no conflict.

In the drawings, a size of a constituent element, a thickness of a layer or an area of the layer may be sometimes exaggerated for clarity. Therefore, any implementation of the present disclosure is not necessarily limited to sizes shown in the drawings, and shapes and sizes of components in the drawings do not reflect true proportions. In addition, the drawings schematically show ideal examples, and any implementation of the present disclosure is not limited to the shapes or values shown in the drawings.

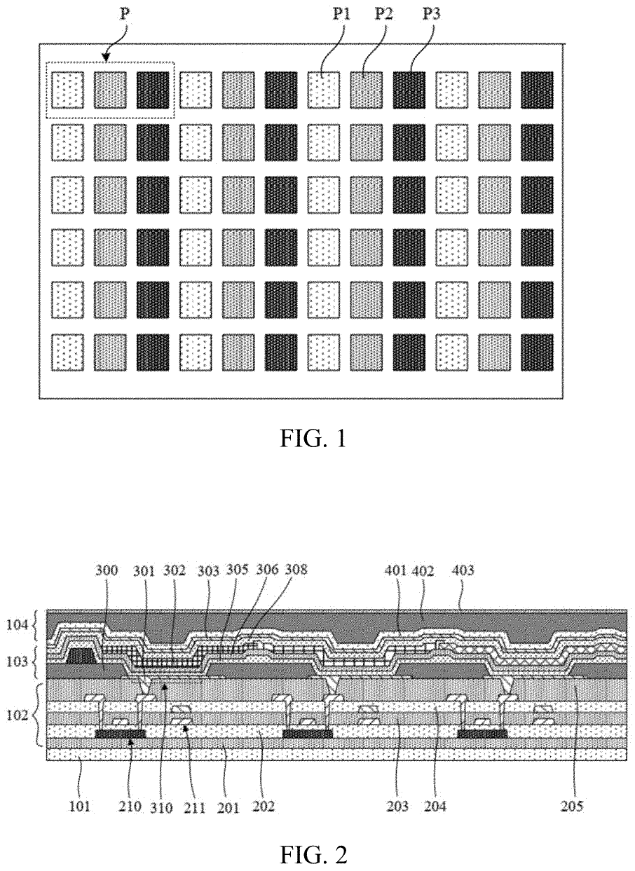

FIG. 1 is a schematic diagram of a planar structure of a display area of a display substrate. As shown in FIG. 1, the display area may include a plurality of pixel units P arranged in a matrix. At least one of the plurality of pixel units P includes a first sub-pixel P1 emitting light of a first color, a second sub-pixel P2 emitting light of a second color, and a third sub-pixel P3 emitting light of a third color. The first sub-pixel P1, the second sub-pixel P2, and the third sub-pixel P3 each include a light emitting device and a pixel driving circuit driving the light emitting device to emit light. The first sub-pixel P1, the second sub-pixel P2, and the third sub-pixel P3 may be configured to emit red light, green light, and blue light, respectively. A pixel unit P may also include a sub-pixel emitting light of another color, e.g., a sub-pixel emitting white light. A shape of a sub-pixel in the pixel unit may be rectangular, diamond, pentagonal, hexagonal, etc. When the pixel unit includes three sub-pixels, the three sub-pixels may be arranged in a row, in a column, or in a “ [symbol] ” shape; and when the pixel unit includes four sub-pixels, the four sub-pixels may be arranged in a row, in a column, or in a square shape, which is not limited in the present disclosure.

FIG. 2 is a schematic diagram of a sectional structure of a display area of a display substrate, illustrating a structure of three sub-pixels in an OLED display substrate. As shown in FIG. 2, on a plane perpendicular to the display substrate, the display substrate may include a driving circuit layer 102 arranged on a base substrate 101, a light emitting structure layer 103 arranged on a side of the driving circuit layer 102 away from the base substrate 101, and an encapsulation structure layer 104 arranged on a side of the light emitting structure layer 103 away from the base substrate 101. The driving circuit layer 102 includes a pixel driving circuit. The light emitting structure layer 103 includes a plurality of OLED light emitting devices 310 each connected with a corresponding pixel driving circuit. In some possible implementations, the display substrate may include another film layer, such as a post spacer, etc., which is not limited in the present disclosure.

In some exemplary embodiments, the base substrate 101 may be a flexible base substrate or may be a rigid base substrate. The flexible base substrate may include a first flexible material layer, a first inorganic material layer, a semiconductor layer, a second flexible material layer, and a second inorganic material layer which are stacked. Materials of the first flexible material layer and the second flexible material layer may be polyimide (PI), polyethylene terephthalate (PET), a surface-treated polymer soft film, etc.; materials of the first inorganic material layer and the second inorganic material layer may be silicon nitride (SiNx), or silicon oxide (SiOx), etc., for improving water-resistance and oxygen-resistance of the base substrate, and a material of the semiconductor layer may be amorphous silicon (a-si).

In some exemplary embodiments, as shown in FIG. 2, a driving circuit layer 102 of each sub-pixel may include a plurality of transistors and a storage capacitor constituting a pixel driving circuit, and an example is illustrated in FIG. 2 where each sub-pixel includes a driving transistor and a storage capacitor. In some possible implementations, the driving circuit layer 102 of each sub-pixel may include: a first insulating layer 201 arranged on a base substrate 101; an active layer arranged on the first insulating layer 201; a second insulating layer 202 covering the active layer; a gate electrode and a first capacitor electrode arranged on the second insulating layer 202; a third insulating layer 203 covering the gate electrode and the first capacitor electrode; a second capacitor electrode arranged on the third insulating layer 203; a fourth insulating layer 204 covering the second capacitor electrode, the second insulating layer 202, the third insulating layer 203, and the fourth insulating layer 204 being provided with via holes exposing the active layer; a source electrode and a drain electrode arranged on the fourth insulating layer 204, the source electrode and the drain electrode being respectively connected with the active layer through via holes; and a planarization layer 205 covering the aforementioned structure, the planarization layer 205 being provided with a via hole exposing the drain electrode. The active layer, the gate electrode, the source electrode, and the drain electrode constitute a driving transistor 210. The first capacitor electrode and the second capacitor electrode constitute a storage capacitor 211.

In some exemplary embodiments, as shown in FIG. 2, the light emitting structure layer 103 may include an anode 301, a pixel definition layer 300, a cathode 303, and an organic functional layer located between the anode 301 and the cathode 303, the organic functional layer at least including a light emitting layer 302. The anode 301 is arranged on the planarization layer 205, and is connected with the drain electrode of the driving transistor 210 through a via hole provided on the planarization layer 205. The pixel definition layer 300 is arranged on the anode 301 and the planarization layer 205, and is provided with a pixel opening exposing the anode 301. In some examples, the light emitting layer 302 is at least partially arranged in the pixel opening and is connected with the anode 301, and the cathode 303 is arranged on and connected to the light emitting layer 302. In some other examples, the organic functional layer may also include a hole injection layer, a hole transport layer 305, and an electron block layer 306 that are located between the anode 301 and the light emitting layer 302 and stacked sequentially on the anode 301, and a hole block layer, an electron transport layer 308, and an electron injection layer that are located between the light emitting layer 302 and the cathode 303 and stacked sequentially on the light emitting layer 302. The anode 301, the organic functional layer, and the cathode 303 of each sub-pixel form an OLED light emitting device 310, which is configured to emit light of a corresponding color under driving of a corresponding pixel driving circuit. In some examples, a light emitting layer 302 of each sub-pixel is located in a sub-pixel area where it is located, and edges of light emitting layers of adjacent sub-pixels may overlap or may be separated from each other. Any film layer of organic functional layers of all sub-pixels other than light emitting layers may be an integral connected film layer covering all the sub-pixels, which may be called a common layer.

In some exemplary embodiments, the encapsulation structure layer 104 may include a first encapsulation layer 401, a second encapsulation layer 402, and a third encapsulation layer 403 which are stacked. The first encapsulation layer 401 and the third encapsulation layer 403 may be made of an inorganic material, the second encapsulation layer 402 may be made of an organic material, and the second encapsulation layer 402 is arranged between the first encapsulation layer 401 and the third encapsulation layer 403, which may ensure that external moisture cannot enter the light emitting device 310.

The inventor of the present application has found that in some OLED devices, such as a green-light OLED device, a host material of a light emitting layer adopts an exciplex, including an N-type material and a P-type material. A material of an electron block layer is generally an aromatic amine material, which is a strong electron-donating material, and is unstable to electrons and excitons. The electron block layer may possibly form, at an interface in contact with the light emitting layer, an exciplex with the N-type material in the host material. If a luminescence spectrum (a PL spectrum) of the formed exciplex coincides well with an absorption spectrum of a dopant material in the light emitting layer, the exciplex at the interface formed by the material of the electron block layer and the N-type material in the host material of the light emitting layer will participate in a light emitting process, thus accelerating breakdown of the electron block layer, leading to degradation of performance of a device and reducing service life of the device.

An embodiment of the present disclosure provides an organic light emitting device, including an anode, a cathode, a light emitting layer arranged between the anode and the cathode, and an electron block layer arranged on a side of the light emitting layer facing the anode, the light emitting layer including a host material and a dopant material, and the host material including an N-type material and a P-type material.

In the embodiment of the present disclosure, the N-type material in the host material of the light emitting layer may be referred to as an N-host material, the P-type material in the host material of the light emitting layer may be referred to as a P-host material, and the electron block layer may be referred to as an EBL.

In some exemplary embodiments, the material of the electron block layer and the N-type material satisfy:

2.75eV≤|LUMO_{N-host}−HOMO_{EBL}|<3.05eV;

0.3<|HOMO_{N-host}−HOMO_{EBL}|≤1eV, and |HOMO_{EBL}|<|HOMO_{N-host}|,

wherein LUMO_{N-host} is the lowest unoccupied molecular orbit energy level of the N-type material, HOMO_{EBL} is the highest occupied molecular orbit energy level of the material of the electron block layer, and HOMO_{N-host} is the highest occupied molecular orbit energy level of the N-type material; a difference between a peak wavelength of a luminescence spectrum curve of an exciplex formed by the material of the electron block layer and the N-type material and an absorption band edge wavelength of an absorption spectrum curve of the dopant material is Δλ, Δλ>30 nm.

In the embodiment of the present disclosure, by defining the above energy level relationship between LUMO_{N-host} and HOMO_{EBL} and defining Δλ>30 nm, it can be ensured that a PL spectrum (a luminescence spectrum) of an exciplex formed by the material of the electron block layer and the N-host material is far away from an absorption spectrum of the dopant material, so that the exciplex formed by the material of the electron block layer and the N-host material does not participate in light emitting, thus reducing breakdown of the material of the electron block layer and improving the service life of the device. In addition, by matching the energy level relationship between HOMO_{N-host} and HOMO_{EBL}, it can be ensured that holes can be better injected into the light emitting layer, thus ensuring light emitting efficiency of the device.

In some exemplary embodiments, the organic light emitting device further includes a hole transport layer (HTL) arranged between the anode and the electron block layer, a material of the hole transport layer and the material of the electron block layer satisfy: 0 eV≤|HOMO_{HTL}−HOMO_{EBL}|≤0.2 eV, wherein HOMO_{HTL} is the highest occupied molecular orbit energy level of the material of the hole transport layer.

In this example, by matching the HOMO energy level relationship between the material of the hole transport layer and the material of the electron block layer, it is beneficial to transport of holes to the electron block layer, which is therefore beneficial to improvement of the light emitting efficiency of the device.

Herein, the highest occupied molecular orbit energy level is referred to as a HOMO energy level, and the lowest unoccupied molecular orbit energy level is referred to as a LUMO energy level. A magnitude relationship of HOMO or LUMO energy levels of different materials refers to a magnitude relationship of absolute values of values of HOMO or LUMO energy levels.

As shown in FIG. 4, ΔE1 is a difference between HOMO energy levels of a HTL material and an EBL material, 0≤ΔE1≤0.2. ΔE2 is a difference between a LUMO energy level of an N-host material and a HOMO energy level of the EBL material, 2.75≤ΔE2≤3.05. ΔE3 is a difference between a HOMO energy level of the EBL material and a HOMO energy level of the N-host material, and the HOMO energy level of the EBL material is lower than that of the N-host material, wherein 0.3<ΔE3<1.

In some exemplary embodiments, the material of the electron block layer may be as shown in Formula (1).

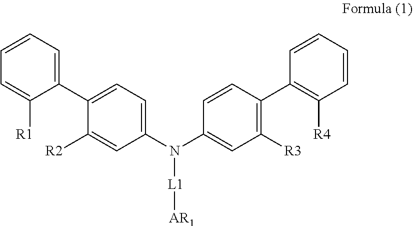

In Formula (1), L1 is a single bond, a benzene ring, or a biphenyl.

R1, R2, R3, and R4 are independently selected from: hydrogen, CHO, C(═O)R5, P(═O)R5, S(═O)R5, cyano, nitro-silyl, boryl, hydroxyl, carboxyl, C1-C4 linear alkyl, C3-C40 cycloalkyl or branched alkyl, C2-C40 alkenyl or alkynyl, and aryl or heteroaryl having 5-60 ring atoms, and may form a ring with one another, wherein R5 in C(═O)R5, P(═O)R5, and S(═O)R5 is independently selected from: C1-C4 linear alkyl, C3-C40 cycloalkyl or branched alkyl, C2-C40 alkenyl or alkynyl, and aryl or heteroaryl having 5-60 ring atoms.

AR1 is any one of the following: substituted or unsubstituted diphenylfluorene, substituted or unsubstituted spirobifluorene, and substituted or unsubstituted spirofluorene heteroanthracene; and any C atom in AR1 may be substituted by a heteroatom which may be any one or more of O, S, N, and Si.

In some examples, AR1 may be selected from any one of the following structures.

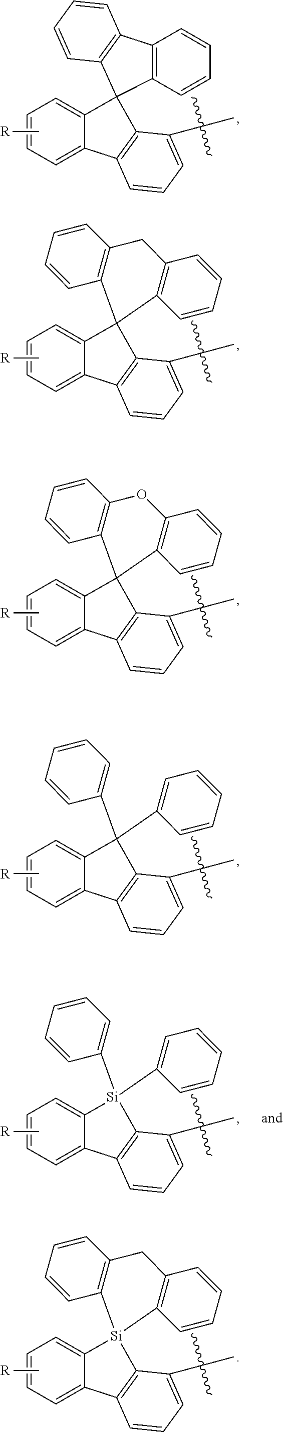

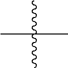

represents a position connected to L1, and R represents H or hydrocarbyl on a spiro ring (H on the spiro ring may be substituted by alkyl or hydrocarbyl).

In some examples of this embodiment, the material of the electron block layer may include any one or more of the following.

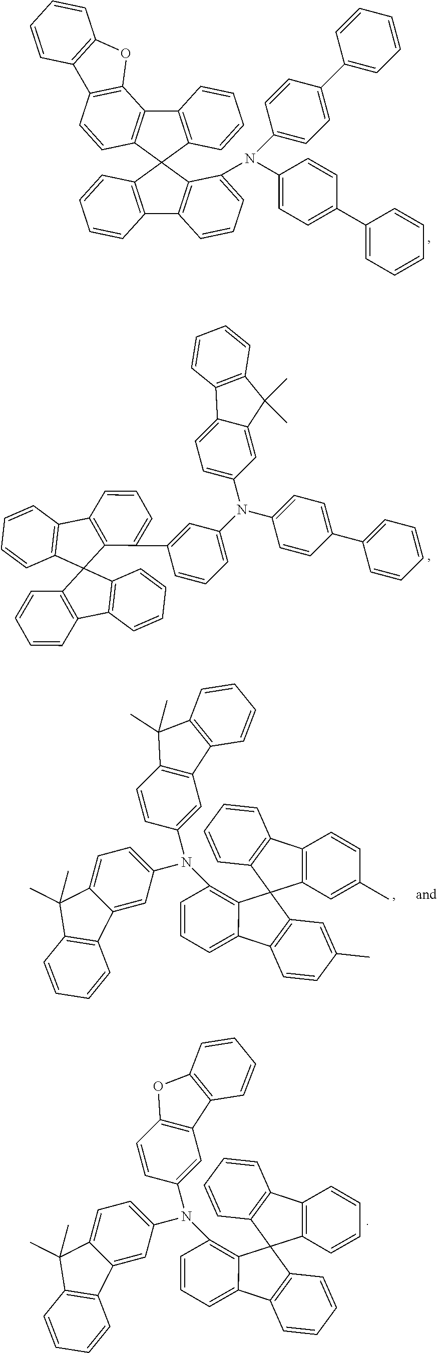

In some exemplary embodiments, a structure of the N-type material in the host material of the light emitting layer may be as shown in Formula (2).

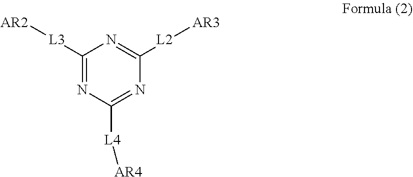

L2, L3, and L4 may be independently a single bond, a benzene ring, or a biphenyl.

AR2 may be selected from the following structures.

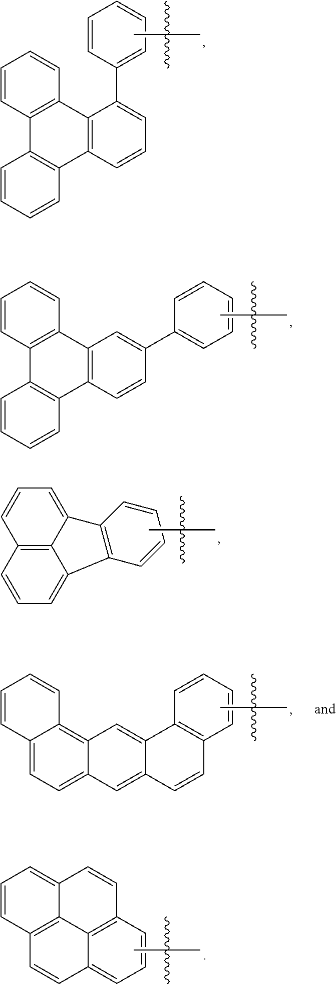

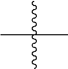

represents a position connected to L3.

AR3 and AR4 are independently selected from: substituted or unsubstituted C6-C30 aryl, and substituted or unsubstituted heteroaryl having 5-30 ring atoms.

In an example of this embodiment, the N-type material in the host material of the light emitting layer may be as follows.

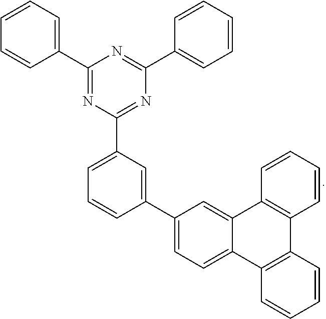 [SMILES: c1ccc(-c2nc(-c3ccccc3)nc(-c3cccc(-c4ccc5c6ccccc6c6ccccc6c5c4)c3)n2)cc1]

In some exemplary embodiments, the P-type material in the host material of the light emitting layer may be as follows.

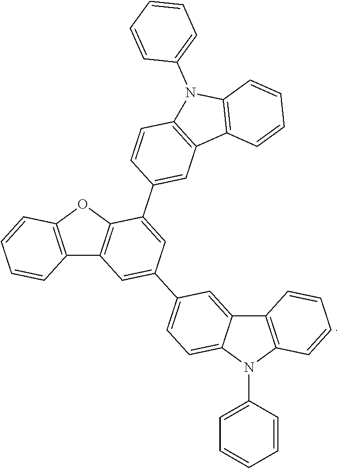 [SMILES: c1ccc(-n2c3ccccc3c3cc(-c4cc(-c5ccc6c(c5)c5ccccc5n6-c5ccccc5)c5oc6ccccc6c5c4)ccc32)cc1]

In some exemplary embodiments, the light emitting device of an embodiment of the present disclosure may be a green-light light emitting device.

In some exemplary embodiments, the dopant material of the light emitting layer may be selected from any one or more of the following: coumarin dyes, quinacridone derivatives, polycyclic aromatic hydrocarbons, diamine anthracene derivatives, carbazole derivatives, metal complexes, etc. For example, it may be coumarin 6(C-6), coumarin 545T(C-525T), quinacridone (QA), N,N′-dimethyl quinacridone (DMQA), 5,12-diphenylnaphthalene (DPT), N10,N10′-diphenyl-N10,N10′-dibenzoyl-9,9′-dianthracene-10,10′-diamine (abbreviation: BA-NPB), tris(8-hydroxyquinoline)aluminum (III) (abbreviation: Alq₃), tris(2-phenylpyridine)iridium (Ir(ppy)₃), and acetylacetonatobis(2-phenylpyridine)iridium (Ir(ppy)₂(acac)).

A structural formula of tris(2-phenylpyridine)iridium (Ir(ppy)₃) is:

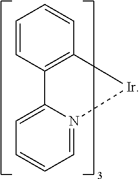

In some exemplary embodiments, a doping ratio of the dopant material in the light emitting layer may be 1 wt %-10 wt %. A doping ratio refers to a proportion of a dopant material in a light emitting layer in the film layer, which may be a mass percentage. In preparation of a light emitting layer, a host material and a dopant material of the light emitting layer may be co-evaporated by a multi-source evaporation process, so that the host material and the dopant material are uniformly dispersed in the light emitting layer, and a doping ratio may be adjusted and controlled by controlling an evaporation rate of the dopant material during the evaporation process, or by controlling an evaporation rate ratio of the host material to the dopant material.

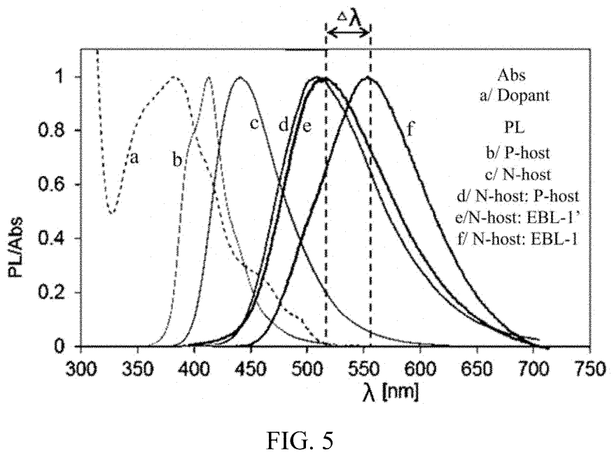

FIG. 5 shows a luminescence spectrum (a PL spectrum) curve f of an exciplex formed by a material (EBL-1) of an electron block layer and an N-host material, a PL spectrum curve c of the N-host material, a PL spectrum curve b of a P-host material, and a PL spectrum curve d of an N-host:P-host blend material in some devices of examples of the present disclosure; a PL spectrum curve e of a blend material of a material (EBL-1′) of an electron block layer and an N-host material in a device of a comparative example; and an absorption spectrum curve a of a dopant material (Dopant) of a light emitting layer in a device of an example of the present disclosure. In FIG. 5, an abscissa λ represents a wavelength, and an ordinate represents a luminous intensity of a PL spectrum and an absorbance (Abs) of an absorption spectrum. An absorbance of a dopant material of a light emitting layer is measured by ultraviolet-visible spectrophotometry (UV-vis) to obtain an absorption spectrum curve a of the dopant material of the light emitting layer. In a spectrum diagram shown in FIG. 5, a material EBL-1 of an electron block layer in a device in an example of the present disclosure is

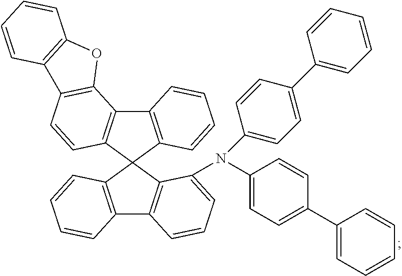 [SMILES: c1ccc(-c2ccc(N(c3ccc(-c4ccccc4)cc3)c3cccc4c3C3(c5ccccc5-4)c4ccccc4-c4c3ccc3c4oc4ccccc43)cc2)cc1]

an N-host material is

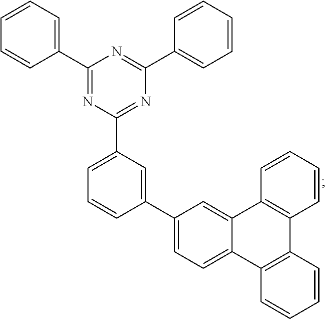 [SMILES: c1ccc(-c2nc(-c3ccccc3)nc(-c3cccc(-c4ccc5c6ccccc6c6ccccc6c5c4)c3)n2)cc1]

a P-host material is

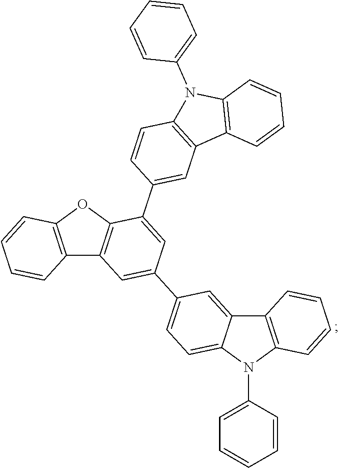 [SMILES: c1ccc(-n2c3ccccc3c3cc(-c4cc(-c5ccc6c(c5)c5ccccc5n6-c5ccccc5)c5oc6ccccc6c5c4)ccc32)cc1]

a material EBL-1′ of an electron block layer in a device in a comparative example is

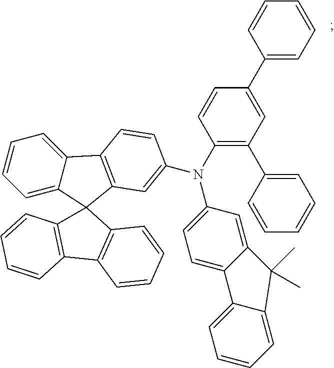 [SMILES: CC1(C)c2ccccc2-c2ccc(N(c3ccc4c(c3)C3(c5ccccc5-c5ccccc53)c3ccccc3-4)c3ccc(-c4ccccc4)cc3-c3ccccc3)cc21]

and a dopant material of a light emitting layer is Ir(ppy)₃.

As can be seen from FIG. 5, compared with curves b, c, d, and e, a luminescence spectrum curve f of an exciplex formed by a material (EBL-1) of an electron block layer and an N-host material in a light emitting layer in a device in an example of the present disclosure is far away from an absorption spectrum curve a of a dopant material in the light emitting layer, and a difference between a peak wavelength of the luminescence spectrum curve f of the exciplex formed and an absorption band edge wavelength of the absorption spectrum curve a of the dopant material is Δλ, Δλ>30 nm. Then, in some exemplary embodiments, when a material of an electron block layer adopts a compound having a structure of the above Formula (1), an N-host material adopts a compound having a structure of the above Formula (2), and a material of the electron block layer and the N-host material satisfy the above energy level relationship, a luminescence spectrum of an exciplex formed by the material of the electron block layer and the N-host material is far away from an absorption spectrum of a dopant material of a light emitting layer, and the exciplex does not participate in a light emitting process, so that breakdown of the material of the electron block layer is alleviated, thereby effectively increasing service life of a device.

In some exemplary embodiments, a material of the hole transport layer (HTL) may be selected from arylamine or carbazole materials having hole transport characteristics. Examples are: 4,4′-bis[N-(1-naphthyl)-N-phenylamino]biphenyl (NPB), N,N′-bis(3-methylphenyl)-N,N′-diphenyl-[1,1′-biphenyl]-4,4′-diamine (TPD), 4-phenyl-4′-(9-phenylfluorene-9-yl)triphenylamine (BAFLP), 4,4′-bis[N-(9,9-dimethylfluorene-2-yl)-N-phenylamino]biphenyl (DFLDPBi), 4,4′-bis(9-carbazolyl)biphenyl (CBP), 9-phenyl-3-[4-(10-phenyl-9-anthryl)phenyl]-9H-carbazole (PCzPA), etc.

In some examples, a material of the hole transport layer (HTL) may include following.

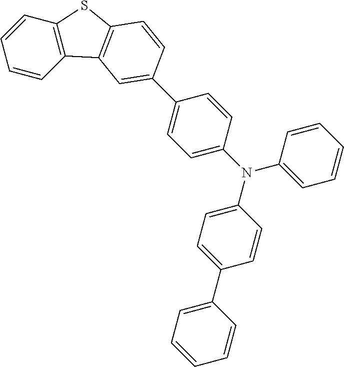 [SMILES: c1ccc(-c2ccc(N(c3ccccc3)c3ccc(-c4ccc5sc6ccccc6c5c4)cc3)cc2)cc1]

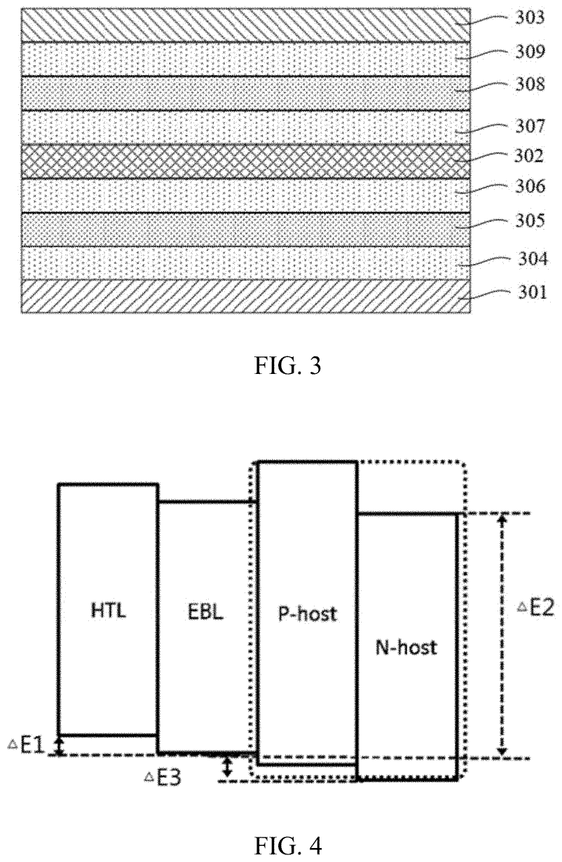

In some exemplary embodiments, as shown in FIG. 3, the light emitting device includes an anode 301, a hole injection layer 304, a hole transport layer 305, an electron block layer 306, a light emitting layer 302, a hole block layer 307, an electron transport layer 308, an electron injection layer 303, and a cathode 303 which are stacked sequentially. The hole injection layer 304 may reduce a hole injection barrier and improve a hole injection efficiency. The hole transport layer 305 may improve a hole transport rate, and may also reduce the hole injection barrier and improve the hole injection efficiency. The electron block layer 306 may block electrons and excitons in the light emitting layer from migrating to a side where the anode is located, and improve a light emitting efficiency. The hole block layer 307 may block holes and excitons in the light emitting layer from migrating to a side where the cathode is located, and improve the light emitting efficiency. The electron transport layer 308 may increase an electron transport rate. The electron injection layer 309 may reduce an electron injection barrier and improve an electron injection efficiency.

In some exemplary embodiments, the anode 301 may be made of a material having a high work function. For a bottom emission type OLED, the anode 301 may be made of a transparent oxide material, such as indium tin oxide (ITO) or indium zinc oxide (IZO), and a thickness of the anode may be about 80 nm to 200 nm. For a top emission type OLED, the anode 301 may be made of a composite structure of metal and transparent oxide, such as Ag/ITO, Ag/IZO, or ITO/Ag/ITO. A thickness of a metal layer in the anode may be about 80 nm to 100 nm, and a thickness of the transparent oxide in the anode 301 may be about 5 nm to 20 nm.

In some exemplary embodiments, the cathode 303 may be formed by evaporation using a metal material which may be magnesium (Mg), silver (Ag), or aluminum (Al), or an alloy material such as a Mg:Ag alloy. A thickness of the cathode may be about 150 nm.

In some exemplary embodiments, a material of a hole injection layer may be 4,4′,4″-tris[2-naphthylphenylamino]triphenylamine (2-TNATA), and a structural formula of 2-TNATA is:

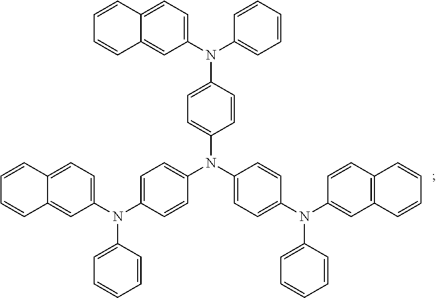 [SMILES: c1ccc(N(c2ccc(N(c3ccc(N(c4ccccc4)c4ccc5ccccc5c4)cc3)c3ccc(N(c4ccccc4)c4ccc5ccccc5c4)cc3)cc2)c2ccc3ccccc3c2)cc1]

or, a material of a hole injection layer may be a mixed material of a hole transport material (a host material) and a p-type dopant material, for example, a material formed by doping MoO₃ (molybdenum trioxide) in TAPC (4,4′-cyclohexylbis[N,N-bis(4-methylphenyl)aniline]), i.e., TAPC:MoO₃. A thickness of the hole injection layer may be about 60 nm.

In some exemplary embodiments, a material of an electron transport layer may include any one or more of the following: 8-hydroxyquinoline lithium (Liq) and 8-hydroxyquinoline aluminum (Alq₃). Structural formulas of 8-hydroxyquinoline lithium (Liq) and 8-hydroxyquinoline aluminum (Alq₃) are as follows respectively.

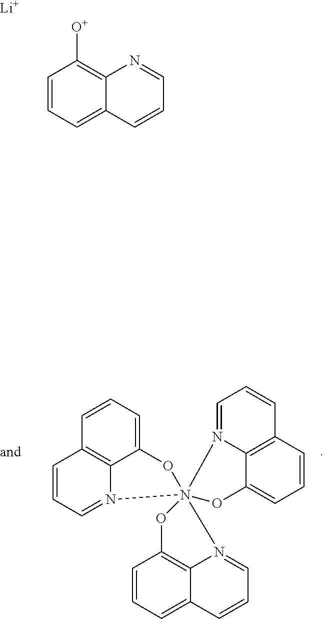

In some exemplary embodiments, a material of an electron injection layer may be lithium fluoride (LiF), ytterbium (Yb), magnesium (Mg), calcium (Ca), or the like.

In some exemplary embodiments, a thickness of a hole injection layer may be about 60 nm, a thickness of a hole transport layer may be about 60 nm, a thickness of an electron block layer may be about 30 nm, a thickness of a light emitting layer may be about 30 nm, a thickness of a hole block layer may be about 10 nm, a thickness of an electron transport layer may be about 40 nm, and a thickness of an electron injection layer may be about 0.2 nm.

In some exemplary embodiments, a display substrate including an OLED device may be prepared by the following preparation method. First, a driving circuit layer is formed on a base substrate through a patterning process. A driving circuit layer of each sub-pixel may include a driving transistor and a storage capacitor constituting a pixel driving circuit. Then, a planarization layer is formed on a base substrate on which the aforementioned structure is formed. A via hole exposing a drain electrode of the driving transistor is formed on a planarization layer of each sub-pixel. Then, an anode is formed by a patterning process on the base substrate on which the aforementioned structure is formed. An anode of each sub-pixel is connected with the drain electrode of the driving transistor through the via hole on the planarization layer. Then, a pixel definition layer is formed by a patterning process on the base substrate on which the aforementioned structure is formed. A pixel opening exposing the anode is formed on the pixel definition layer of each sub-pixel, and each pixel opening serves as a light emitting area of each sub-pixel. Then, on the base substrate on which the aforementioned structure is formed, first, an open mask is used to evaporate a hole injection layer and a hole transport layer sequentially. The hole injection layer and the hole transport layer are common layers. That is, hole injection layers of all sub-pixels are integrally connected, and hole transport layers of all sub-pixels are integrally connected. The hole injection layers and the hole transport layers have substantially the same area, but different thicknesses. Subsequently, a fine metal mask is used to evaporate an electron block layer and a red light emitting layer, an electron block layer and a green light emitting layer, and an electron block layer and a blue light emitting layer respectively in different sub-pixels. Electron block layers of adjacent sub-pixels and light emitting layers of adjacent sub-pixels may slightly overlap or may be separated from each other. Subsequently, an open mask is used to evaporate a hole block layer, an electron transport layer, an electron injection layer, and a cathode sequentially. The hole block layer, the electron transport layer, the electron injection layer, and the cathode are all common layers. That is, hole block layers of all sub-pixels are integrally connected, electron transport layers of all sub-pixels are integrally connected, electron injection layers of all sub-pixels are integrally connected, and cathodes of all sub-pixels are integrally connected.

In some exemplary embodiments, a multi-source co-evaporation method may be used for evaporation of a light emitting layer to form the light emitting layer including a host material and a dopant material. A doping ratio of the dopant material may be adjusted and controlled by controlling an evaporation rate of the dopant material in an evaporation process, or by controlling an evaporation rate ratio of the host material to the dopant material.

Next, performance of devices of the embodiments of the present disclosure is compared with performance of the devices of two comparative embodiments. The devices of the embodiments of the present disclosure and the devices of the two comparative embodiments all include an anode, a hole injection layer, a hole transport layer, an electron block layer, a light emitting layer, a hole block layer, an electron transport layer, and a cathode which are stacked sequentially. Regarding materials of film layers in a structure of a device, except a material of an electron block layer, materials of other film layers of the devices of the embodiments of the present disclosure are the same as that of the devices of the two comparative embodiments. Materials of electron block layers of a device of Embodiment 1, a device of Embodiment 2, a device of Embodiment 3, and a device of Embodiment 4 of the present disclosure are EBL-1, EBL-2, EBL-3, and EBL-4, respectively, and materials of electron block layers of a device of comparative embodiment 1 and a device of comparative embodiment 2 are EBL-1′ and EBL-2′, respectively.

The materials of related film layers of the devices of the embodiments of the present disclosure and the devices of the two comparative embodiments are as follows.

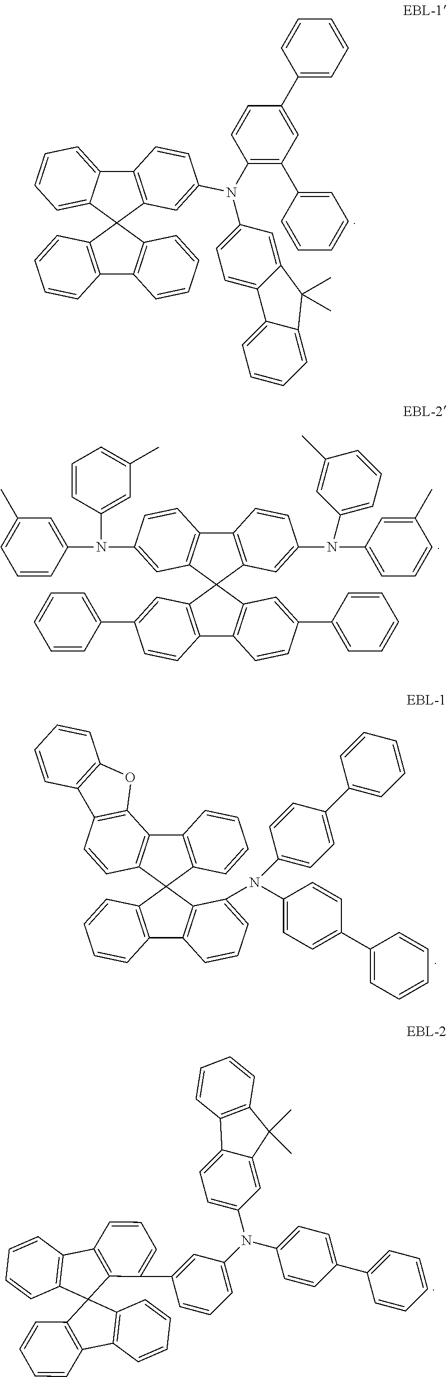 [SMILES: CC1(C)c2ccccc2-c2ccc(N(c3ccc4c(c3)C3(c5ccccc5-c5ccccc53)c3ccccc3-4)c3ccc(-c4ccccc4)cc3-c3ccccc3)cc21 ; Cc1cccc(N(c2cccc(C)c2)c2ccc3c(c2)C2(c4cc(-c5ccccc5)ccc4-c4ccc(-c5ccccc5)cc42)c2cc(N(c4cccc(C)c4)c4cccc(C)c4)ccc2-3)c1 ; c1ccc(-c2ccc(N(c3ccc(-c4ccccc4)cc3)c3cccc4c3C3(c5ccccc5-4)c4ccccc4-c4c3ccc3c4oc4ccccc43)cc2)cc1 ; CC1(C)c2ccccc2-c2ccc(N(c3ccc(-c4ccccc4)cc3)c3cccc(-c4cccc5c4C4(c6ccccc6-c6ccccc64)c4ccccc4-5)c3)cc21]

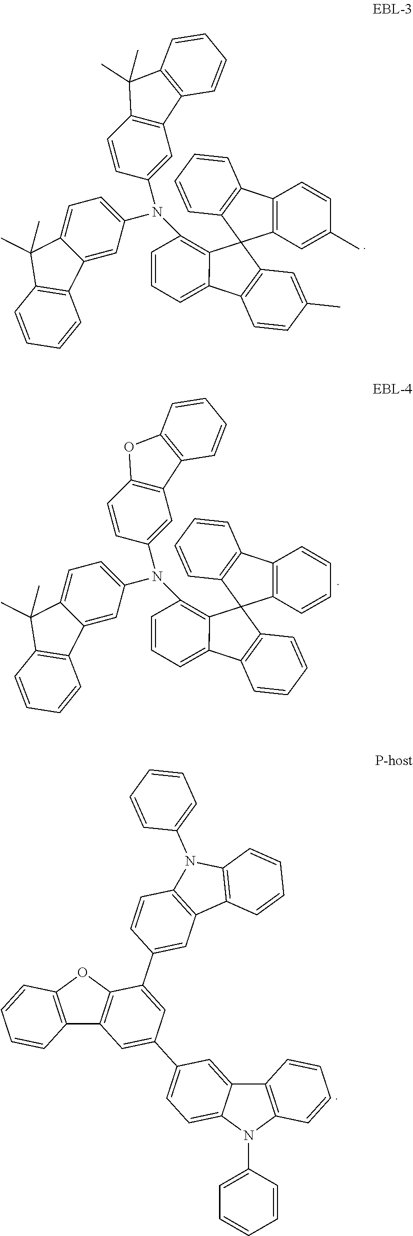

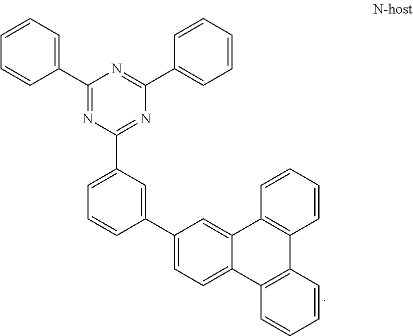 [SMILES: c1ccc(-c2nc(-c3ccccc3)nc(-c3cccc(-c4ccc5c6ccccc6c6ccccc6c5c4)c3)n2)cc1]

A dopant material of a light emitting layer: tris(2-phenylpyridine)iridium (Ir(ppy)₃).

HIL: 2-TNATA.

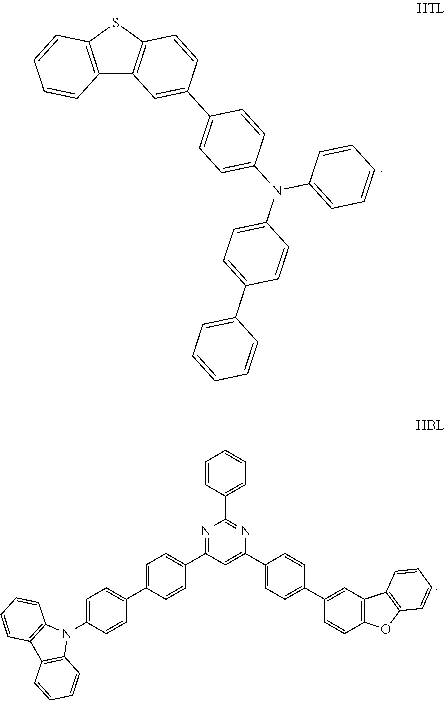 [SMILES: c1ccc(-c2ccc(N(c3ccccc3)c3ccc(-c4ccc5sc6ccccc6c5c4)cc3)cc2)cc1 ; c1ccc(-c2nc(-c3ccc(-c4ccc(-n5c6ccccc6c6ccccc65)cc4)cc3)cc(-c3ccc(-c4ccc5oc6ccccc6c5c4)cc3)n2)cc1]

ETL: 8-hydroxyquinoline aluminum (Alq₃).

EIL: LiF.

Material energy levels of electron block layers, P-host, and N-host of the devices of the embodiments of the present disclosure and the devices of two comparative embodiments are shown in Table 1 below.

TABLE 1
Material energy level parameters

| | HOMO/eV | LUMO/eV |
|---|---|---|
| EBL-1′ | −5.44 | −2.31 |
| EBL-2′ | −5.57 | −2.45 |
| EBL-1 | −5.38 | −2.41 |
| EBL-2 | −5.30 | −2.32 |
| EBL-3 | −5.19 | −2.09 |
| EBL-4 | −5.25 | −2.19 |
| P-host | −5.47 | −2.19 |
| N-host | −5.83 | −2.39 |

In Table 1, taking the device of Embodiment 1 of the present disclosure as an example, an energy level relationship between a material (EBL-1) of an electron block layer and an N-host material is calculated. A difference between a LUMO energy level of the N-host material and a HOMO energy level of the EBL-1 material is: ΔE2=|−2.39−(−5.38)|=2.99, satisfying: 2.75≤ΔE2<3.05. A difference between a HOMO energy level of the EBL-1 material and a HOMO energy level of the N-host material is: ΔE3=|−5.38−(−5.83)|=0.45, satisfying: 0.3<ΔE3≤1, and the HOMO energy level of the EBL-1 material is lower than that of the N-host material. Similarly, materials of electron block layers and N-host materials of the devices of Embodiment 2, Embodiment 3, and Embodiment 4 of the present disclosure satisfy the above energy level relationship.

Comparison results of performance between the devices of the embodiments of the present disclosure and the devices of the two comparative embodiments are shown in Table 2.

TABLE 2
Comparison results of device performance

| | Voltage | Efficiency | Service life (T95) |
|---|---|---|---|
| Comparative embodiment 1 | 100% | 100% | 100% |
| Comparative embodiment 2 | 113% | 102% | 105% |
| Embodiment 1 | 103% | 98.5% | 153% |
| Embodiment 2 | 101% | 99.3% | 138% |
| Embodiment 3 | 103% | 97.8% | 169% |
| Embodiment 4 | 105% | 96.5% | 192% |

In Table 2, performance data of the devices of comparative embodiment 2 and embodiments 1-4 are described with reference to performance data of the device of comparative embodiment 1. As can be seen from Table 2, for the device of comparative embodiment 2, an efficiency and service life are not significantly increased as compared with the device of comparative embodiment 1, but a voltage is relatively large. Efficiencies and voltages of the devices of embodiments 1-4 of the present disclosure are equivalent to those of comparative embodiments 1 and 2, but service life of the devices of embodiments 1-4 of the present disclosure is significantly improved as compared with that of comparative embodiments 1 and 2. This indicates: in the embodiments of the present disclosure, as a luminescence spectrum of an exciplex formed by a material of an electron block layer and an N-type material in a host material of a light emitting layer is far away from an absorption spectrum of a dopant material of the light emitting layer, the exciplex does not participate in a light emitting process, thus effectively improving service life of a device without affecting a voltage and efficiency of the device. In Table 2, service life of a device is measured by T95. T95 refers to a luminous duration required for brightness of a light emitted by a device to decay to 95% of initial brightness.

An embodiment of the present disclosure further provides a display apparatus including the aforementioned organic light emitting device. The display apparatus may be any product or component with a display function such as a mobile phone, a tablet computer, a television, a display, a notebook computer, a digital photo frame, a navigator, an in-vehicle display, a smart watch, a smart bracelet.

Although the embodiments disclosed in the present disclosure are as described above, the described contents are only the embodiments for facilitating understanding of the present disclosure, which are not intended to limit the present disclosure. Any person skilled in the field to which the present disclosure pertains may make any modifications and variations in the forms and details of implementation without departing from the spirit and the scope disclosed in the present disclosure, but the patent protection scope of the present application should still be subject to the scope defined by the appended claims.

What is claimed is:

1. An organic light emitting device, comprising an anode, a cathode, a light emitting layer arranged between the anode and the cathode, and an electron block layer arranged on a side of the light emitting layer facing the anode; wherein the light emitting layer comprises a host material and a dopant material, the host material comprises an N-type material and a P-type material,
a material of the electron block layer and the N-type material satisfy:
2.75eV<|LUMO_{N-host}−HOMO_{EBL}|<3.05eV;
0.3<|HOMO_{N-host}−HOMO_{EBL}|≤1eV, and |HOMO_{EBL}|<|HOMO_{N-host}|,
wherein LUMO_{N-host} is a lowest unoccupied molecular orbit energy level of the N-type material, HOMO_{EBL} is a highest occupied molecular orbit energy level of the material of the electron block layer, and HOMO_{N-host} is a highest occupied molecular orbit energy level of the N-type material;
a difference between a peak wavelength of a luminescence spectrum curve of an exciplex formed by the material of the electron block layer and the N-type material and an absorption band edge wavelength of an absorption spectrum curve of the dopant material is Δλ, Δλ>30 nm.

2. The organic light emitting device according to claim 1, further comprising a hole transport layer arranged between the anode and the electron block layer, wherein a material of the hole transport layer and the material of the electron block layer satisfy: 0 eV≤|HOMO_{HTL}−HOMO_{EBL}|≤0.2 eV, wherein HOMO_{HTL} is a highest occupied molecular orbit energy level of the material of the hole transport layer.

3. The organic light emitting device according to claim 1, wherein the material of the electron block layer comprises a compound having the following structural formula: 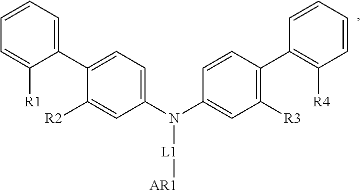
wherein L1 is a single bond, a benzene ring, or a biphenyl;
R1, R2, R3, and R4 are independently selected from: hydrogen, CHO, C(═O)R5, P(═O)R5, S(═O)R5, cyano, nitro-silyl, boryl, hydroxyl, carboxyl, C1-C4 linear alkyl, C3-C40 cycloalkyl or branched alkyl, C2-C40 alkenyl or alkynyl, and aryl or heteroaryl having 5-60 ring atoms, wherein R5 in C(═O)R5, P(═O)R5, and S(═O)R5 is independently selected from: C1-C4 linear alkyl, C3-C40 cycloalkyl or branched alkyl, C2-C40 alkenyl or alkynyl, and aryl or heteroaryl having 5-60 ring atoms;
AR1 is any one of the following: substituted or unsubstituted diphenylfluorene, substituted or unsubstituted spirobifluorene, and substituted or unsubstituted spirofluorene heteroanthracene.

4. The organic light emitting device according to claim 3, wherein AR1 is selected from any one of the following structures: 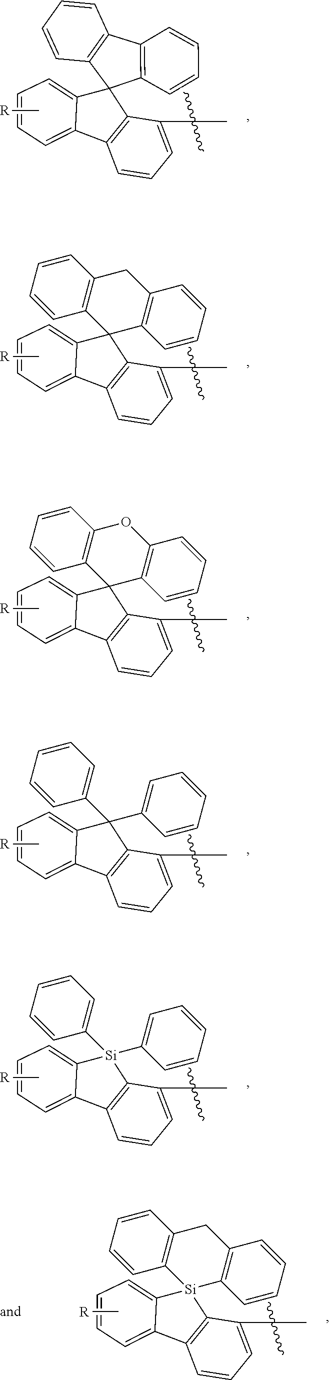
wherein 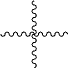
represents a position connected to L1, and R represents hydrogen or hydrocarbyl on a spiro ring.

5. The organic light emitting device according to claim 3, wherein the material of the electron block layer comprises any one or more of the following:

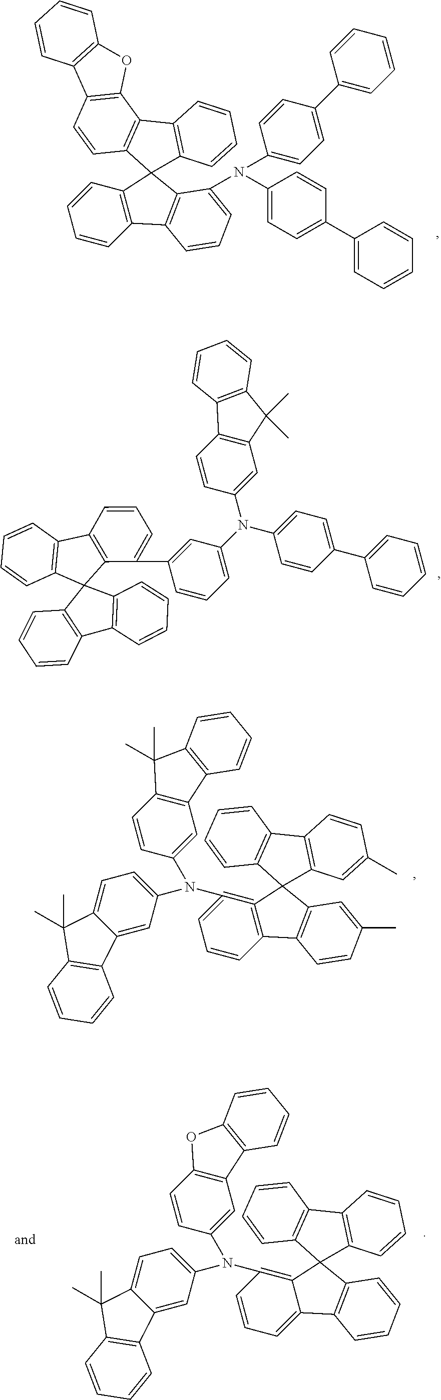

6. The organic light emitting device according to claim 1, wherein the N-type material comprises a compound having the following structural formula: 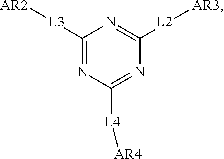
wherein L2, L3, and L4 are independently a single bond, a benzene ring, or a biphenyl;
AR2 is selected from the following structures: 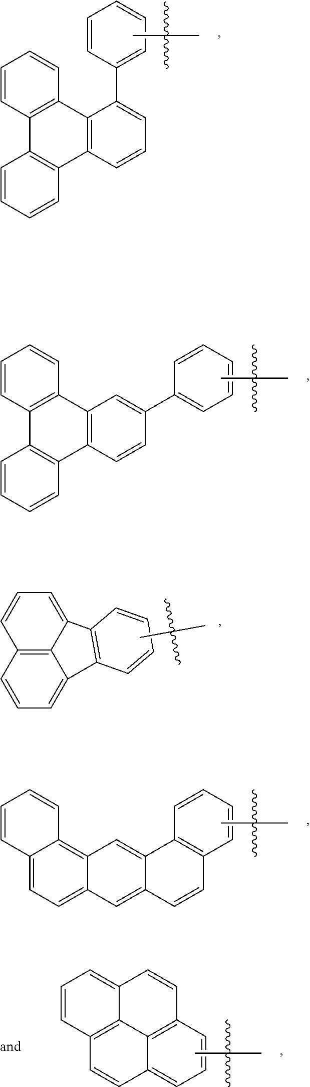
wherein 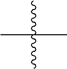
represents a position connected to L3;
AR3 and AR4 are independently selected from: substituted or unsubstituted C6-C30 aryl, and substituted or unsubstituted heteroaryl having 5-30 ring atoms.

7. The organic light emitting device according to claim 6, wherein the N-type material comprises a compound having the following structural formula:

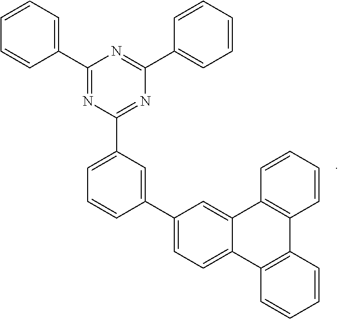 [SMILES: c1ccc(-c2nc(-c3ccccc3)nc(-c3cccc(-c4ccc5c6ccccc6c6ccccc6c5c4)c3)n2)cc1]

8. The organic light emitting device according to claim 1, wherein the P-type material comprises a compound having the following structural formula:

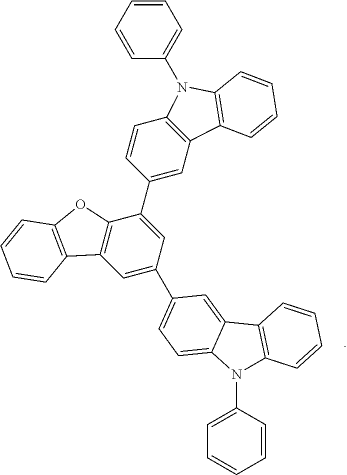 [SMILES: c1ccc(-n2c3ccccc3c3cc(-c4cc(-c5ccc6c(c5)c5ccccc5n6-c5ccccc5)c5oc6ccccc6c5c4)ccc32)cc1]

9. The organic light emitting device according to claim 1, wherein the dopant material comprises any one or more of the following: coumarin dyes, quinacridone derivatives, polycyclic aromatic hydrocarbons, diamine anthracene derivatives, carbazole derivatives, and metal complexes.

10. The organic light emitting device according to claim 2, wherein the material of the hole transport layer comprises a compound having the following structural formula:

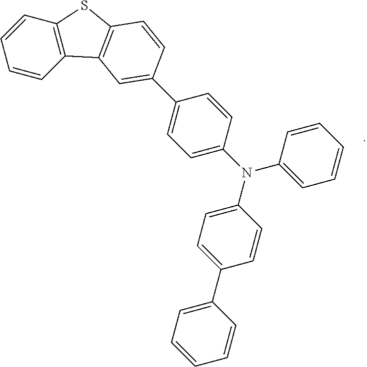 [SMILES: c1ccc(-c2ccc(N(c3ccccc3)c3ccc(-c4ccc5sc6ccccc6c5c4)cc3)cc2)cc1]

11. The organic light emitting device according to claim 2, further comprising a hole injection layer arranged between the hole transport layer and the anode, wherein a material of the hole injection layer comprises 4,4′,4″-tris[2-naphthylphenylamino]triphenylamine.

12. The organic light emitting device according to claim 1, further comprising a hole block layer arranged on a side of the light emitting layer facing the cathode, wherein a material of the hole block layer comprises a compound having the following structural formula:

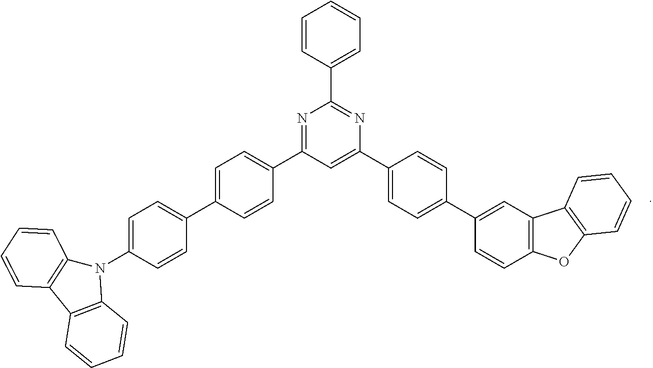 [SMILES: c1ccc(-c2nc(-c3ccc(-c4ccc(-n5c6ccccc6c6ccccc65)cc4)cc3)cc(-c3ccc(-c4ccc5oc6ccccc6c5c4)cc3)n2)cc1]

13. The organic light emitting device according to claim 12, further comprising an electron transport layer arranged between the hole block layer and the cathode, wherein a material of the electron transport layer comprises any one or more of the following: 8-hydroxyquinoline lithium or 8-hydroxyquinoline aluminum.

14. A display apparatus, comprising the organic light emitting device according to claim 1.

15. A display apparatus, comprising the organic light emitting device according to claim 2.

16. A display apparatus, comprising the organic light emitting device according to claim 3.

17. A display apparatus, comprising the organic light emitting device according to claim 6.

18. A display apparatus, comprising the organic light emitting device according to claim 8.

19. A display apparatus, comprising the organic light emitting device according to claim 11.

20. A display apparatus, comprising the organic light emitting device according to claim 12.
